(19) United States
(12) Patent Application Publication
(10) Pub. No.: US 2026/0342303 A1
(43) Pub. Date: Oct. 29, 2026

(54) LC CIRCUIT

(71) Applicant: Murata Manufacturing Co., Ltd., Nagaokakyo-shi (JP)

(72) Inventor: Yusaku HONMA, Nagaokakyo-shi (JP)

(21) Appl. No.: 19/464,755

(22) Filed: Jan. 30, 2026

(30) Foreign Application Priority Data
Feb. 21, 2025 (JP) 2025-026768

(51) Int. Cl. H03H 7/38

(52) U.S. Cl. CPC H03H 7/38

(57) ABSTRACT

An LC circuit includes: a first inductor having a first end electrically coupled to a first terminal and a second end electrically coupled to ground; a first capacitor having a first end electrically coupled to the first terminal and a second end; a second inductor having a first end electrically coupled to the second end of the first capacitor and a second end electrically coupled to ground, and electromagnetically coupled to the first inductor; and a third inductor having a first end electrically coupled to the second end of the first capacitor and a second end electrically coupled to a second terminal, and electromagnetically coupled to the second inductor.

### CROSS REFERENCE TO RELATED APPLICATION

This application claims priority from Japanese Patent Application No. 2025-026768, filed on Feb. 21, 2025. The content of this application is incorporated herein by reference in its entirety.

### BACKGROUND OF THE DISCLOSURE

### 1. Field of the Disclosure

The present disclosure relates to an LC circuit.

### 2. DESCRIPTION OF THE RELATED ART

A matching circuit that includes an autotransformer is available (see Japanese Patent No. 6760515, for example).

In the matching circuit described in Japanese Patent No. 6760515, the autotransformer includes a first terminal, a second terminal, and a common terminal, and is connected between a first port and a second port. A capacitor is shunt-connected to the second terminal, and, along with a portion of the autotransformer, configures a low-pass filter.

There has been a demand for a circuit that has a small circuit size and possesses the function of a high-pass filter with a pole and the function of impedance matching; however, such a circuit is not disclosed in Japanese Patent No. 6760515.

### BRIEF SUMMARY OF THE DISCLOSURE

In view of such circumstances, it is a possible benefit of the present disclosure to provide an LC circuit that possesses the function of a high-pass filter with a pole and the function of impedance matching, and that allows the circuit size to be reduced.

An LC circuit according to one aspect of the present disclosure includes: a first inductor having a first end electrically coupled to a first terminal and a second end electrically coupled to ground; a first capacitor having a first end electrically coupled to the first terminal and a second end; a second inductor having a first end electrically coupled to the second end of the first capacitor and a second end electrically coupled to ground, and electromagnetically coupled to the first inductor; a third inductor having a first end electrically coupled to the second end of the first capacitor and a second end electrically coupled to a second terminal, and electromagnetically coupled to the second inductor.

According to the present disclosure, it is possible to provide an LC circuit that possesses the function of a high-pass filter with a pole and the function of impedance matching, and that allows the circuit size to be reduced.

### BRIEF DESCRIPTION OF THE SEVERAL VIEWS OF THE DRAWINGS

FIG. 1 is a circuit diagram of an LC circuit 101;

FIG. 2 is a circuit diagram of an equivalent circuit 101e of the LC circuit 101;

FIG. 3 is a circuit diagram of a reference circuit 901, which serves as a reference example;

FIG. 4 is a diagram illustrating the simulation results of the frequency variation of S22 plotted on a Smith chart;

FIG. 5 is a diagram illustrating the simulation results of the frequency variation of S21;

FIG. 6 is a circuit diagram of an LC circuit 102;

FIG. 7 is a circuit diagram of an equivalent circuit 102e of the LC circuit 102;

FIG. 8 is a circuit diagram of an LC circuit 103;

FIG. 9 is a circuit diagram of a reception circuit 121 including the LC circuit 101;

FIG. 10 is a circuit diagram of a transmission circuit 122 including the LC circuit 101;

FIG. 11 is a diagram illustrating an example of the layout of inductors 311, 312, and 313 of the LC circuit 101;

FIG. 12 is a diagram illustrating another example of the layout of the inductors 311, 312, and 313 of the LC circuit 101;

FIG. 13 is a diagram illustrating yet another example of the layout of the inductors 311, 312, and 313 of the LC circuit 101; and

FIG. 14 is a diagram illustrating a further example of the layout of the inductors 311, 312, and 313 of the LC circuit 101.

### DETAILED DESCRIPTION OF THE DISCLOSURE

Hereinafter, embodiments of the present disclosure will be described in detail with reference to the drawings. Note that the same reference numerals are assigned to identical elements, and redundant descriptions are omitted as much as possible.

### First Embodiment

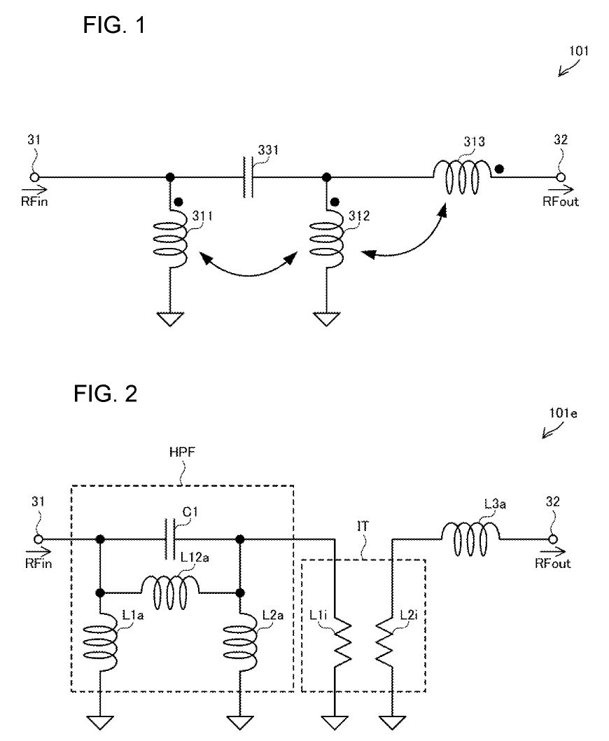

An LC circuit 101 according to a first embodiment will be described. FIG. 1 is a circuit diagram of the LC circuit 101. As illustrated in FIG. 1, the LC circuit 101 includes inductors 311 (first inductor), 312 (second inductor), and 313 (third inductor), and a capacitor 331 (first capacitor).

An input signal RFin is supplied to an input terminal 31 (first terminal). The input signal RFin is, for example, a radio frequency (RF) signal. The input signal RFin passes through the LC circuit 101 and is outputted from an output terminal 32 (second terminal). Hereinafter, a radio frequency signal outputted from the output terminal 32 may be referred to as an output signal RFout.

The capacitor 331 has a first end electrically coupled to the input terminal 31 and a second end. The inductor 311 has a first end electrically coupled to the input terminal 31 and a second end electrically coupled to ground.

The inductor 312 has a first end electrically coupled to the second end of the capacitor 331 and a second end electrically coupled to ground, and is electromagnetically coupled to the inductor 311.

The inductor 313 has a first end electrically coupled to the second end of the capacitor 331 and a second end electrically coupled to the output terminal 32, and is electromagnetically coupled to the inductor 312.

FIG. 2 is a circuit diagram of an equivalent circuit 101e of the LC circuit 101. As illustrated in FIG. 2, the equivalent circuit 101e includes a pole-type high-pass filter (HPF), an ideal transformer (IT), and an inductor L3a.

The pole-type high-pass filter HPF includes inductors L1a, L12a, and L2a and a capacitor C1. The capacitor C1 has a first end electrically coupled to the input terminal 31 and a second end.

The inductor L1a is provided between the first end of the capacitor C1 and ground. The inductor L2a is provided between the second end of the capacitor C1 and ground. The inductor L12ais provided in parallel with the capacitor C1.

The inductors L1a and L2a and the capacitor C1 function as a π-type high-pass filter. Additionally, with the configuration in which the inductor L12a is provided in parallel with the capacitor C1, a pole is generated by LC resonance. The pass characteristics of the high-pass filter will be described in detail later.

The ideal transformer IT includes inductors L1i and L2i, which are electrically coupled to each other. The inductor L1i is provided between the second end of the capacitor C1 and ground. The inductor L2i has a first end connected to the output terminal 32 with the inductor L3a interposed therebetween, and a second end connected to ground.

The ideal transformer IT and the inductor L3a function as a matching circuit that matches the impedance between a circuit provided on the preceding stage of the input terminal 31 and a circuit provided on the subsequent stage of the output terminal 32.

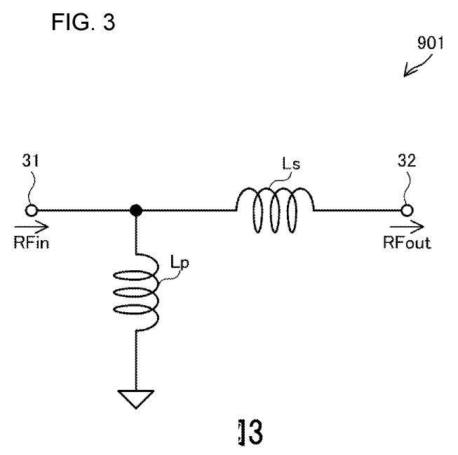

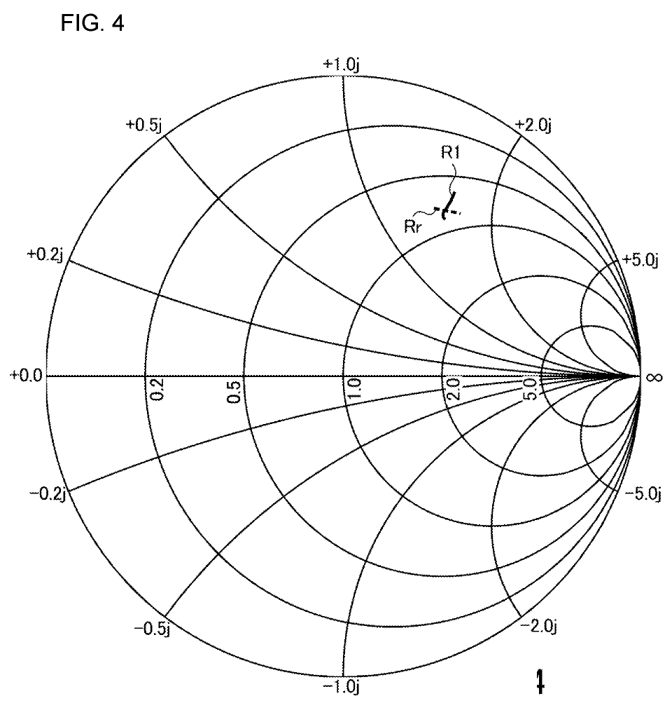

FIG. 3 is a circuit diagram of a reference circuit 901, which serves as a reference example. In the reference circuit 901, a series inductor Ls is provided between the input terminal 31 and the output terminal 32. A parallel inductor Lp is provided between the input terminal 31 and ground.

FIG. 4 is a diagram illustrating the simulation results of the frequency variation of S22 plotted on a Smith chart. Here, S22 is the S-parameter of a signal that is supplied from the output terminal 32 toward the input terminal 31

As illustrated in FIGS. 1 to 4, curve R1 represents the variation of S22 when the frequency is varied from 3.3 GHz to 4.4 GHz, in a case where the input terminal 31 and the output terminal 32 of the LC circuit 101 are used as the input port and the output port, respectively.

Curve Rr represents the variation of S22 when the frequency is varied from 3.3 GHz to 4.4 GHz, in a case where the input terminal 31 and the output terminal 32 of the reference circuit 901 are used as the input port and the output port, respectively.

S22 in the LC circuit 101 and S22 in the reference circuit 901 have similar values in the frequency range from 3.3 GHz to 4.4 GHz. That is, the function of the LC circuit 101 as a matching circuit and the function of the reference circuit 901 as a matching circuit are the same or similar.

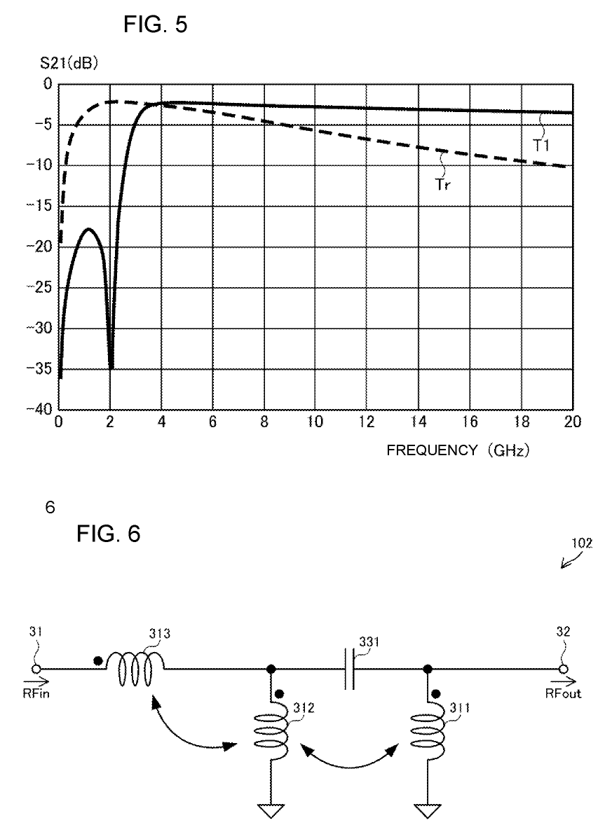

FIG. 5 is a diagram illustrating the simulation results of the frequency variation of S21. Here, S21 is the S-parameter of a signal that passes through the LC circuit 101. Note that the vertical axis indicates S21 in units of "dB". The horizontal axis indicates the frequency in units of "GHz".

As illustrated in FIGS. 1 to 3 and 5, curve Tr represents the frequency variation of S21 when the reference impedance is set to a predetermined value, in a case where the input terminal 31 and the output terminal 32 of the reference circuit 901 are used as the input port and the output port, respectively.

These simulation results are obtained when the inductances of the series inductor Ls and the parallel inductor Lp are 2.4 nH and 4.3 nH, respectively.

Curve T1 represents the frequency variation of S21 when the reference impedance is set to the aforementioned predetermined value, in a case where the input terminal 31 and the output terminal 32 of the LC circuit 101 are used as the input port and the output port, respectively.

These simulation results are obtained when the inductances of the inductors 311, 312, and 313 are 2 nH, 0.9 nH, and 1.6 nH, respectively, and the capacitance of the capacitor C1 is 1.8 pF.

The reference circuit 901 functions as a high-pass filter; however, in the frequency domain above 2 GHz, the loss gradually increases as the frequency increases.

In contrast, in the frequency domain above 4 GHz, the loss of the LC circuit 101 exhibits a smaller variation with respect to frequency and is reduced compared to the loss of the reference circuit 901.

Additionally, in the LC circuit 101, the resonance of the capacitor C1 and the inductor L12a (see FIG. 2) makes it possible to generate a pole around 2 GHz. Accordingly, it is possible to effectively suppress the passage of signals in the frequency region including the pole.

In the LC circuit 101, the inductor 312 and the inductor 311 are electromagnetically coupled to serve as a π-type high-pass filter. Furthermore, the inductor 312 and the inductor 313 are electromagnetically coupled to form an autotransformer, and the autotransformer functions as an impedance matching circuit.

In this manner, by effectively enhancing the magnetic field through sharing the inductor 312, it is possible to supplement the inductances of the inductors 311, 312, and 313. This makes it possible to reduce the size of the inductors 311, 312, and 313, thereby allowing the circuit size of the LC circuit 101 to be reduced.

### Second Embodiment

An LC circuit 102 according to a second embodiment will be described. In the second and subsequent embodiments, descriptions of matters common to those of the first embodiment are omitted, and only the differences are explained. In particular, the same or similar effects achieved by the same or similar configurations are not repeatedly mentioned for each embodiment.

FIG. 6 is a circuit diagram of the LC circuit 102. As illustrated in FIG. 6, the LC circuit 102 according to the second embodiment differs from the LC circuit 101 according to the first embodiment in that the input signal RFin passes in the opposite direction.

In the present embodiment, the first end of the inductor 311 and the first end of the capacitor 331 are connected to the output terminal 32 (first terminal). The second end of the inductor 313 is connected to the input terminal 31 (second terminal).

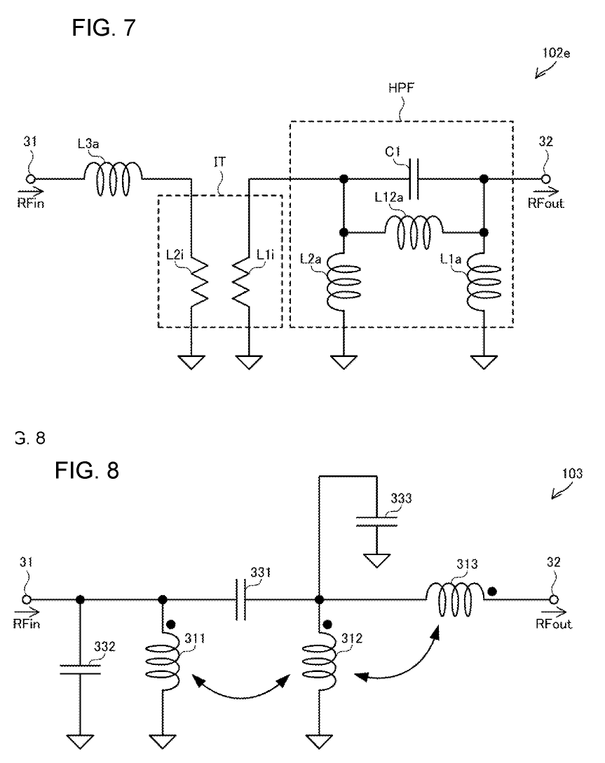

FIG. 7 is a circuit diagram of an equivalent circuit 102e of the LC circuit 102. As illustrated in FIG. 7, in the equivalent circuit 102e, the first end of the capacitor C1 is connected to the output terminal 32. The first end of the inductor L2i is connected to the input terminal 31 with the inductor L3a interposed therebetween.

### Third Embodiment

An LC circuit 103 according to a third embodiment will be described. FIG. 8 is a circuit diagram of the LC circuit 103. As illustrated in FIG. 8, the LC circuit 103 according to the third embodiment differs from the LC circuit 101 according to the first embodiment in that capacitors are provided in parallel with the inductors forming the π-type high-pass filter.

The LC circuit 103 further includes capacitors 332 (second capacitor) and 333 (third capacitor), as compared to the LC circuit 101 illustrated in FIG. 1.

The capacitor 332 has a first end electrically coupled to the input terminal 31 and a second end electrically coupled to ground. The capacitor 333 has a first end electrically coupled to the second end of the capacitor 331 and a second end electrically coupled to ground.

### Effects

Since the LC circuit 101 includes multiple inductors, the input impedance tends to be inductive. In contrast, with the configuration in which the capacitors 332 and 333 are respectively provided in parallel with the inductors 311 and 312, it is possible to enhance the capacitive nature of the input impedance. Specifically, it is possible to make the input impedance closer to the real-valued reference impedance.

### Fourth Embodiment

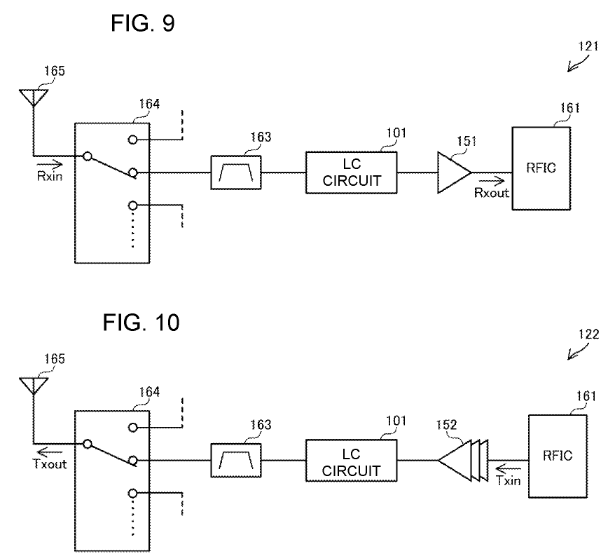

The LC circuit 101 according to a fourth embodiment will be described. FIG. 9 is a circuit diagram of a reception circuit 121 including the LC circuit 101. As illustrated in FIG. 9, the LC circuit 101 according to the fourth embodiment differs from the LC circuit 101 according to the first embodiment in that the LC circuit 101 is specifically incorporated into the reception circuit.

The reception circuit 121 includes a low-noise amplifier 151 (amplifier), a radio-frequency integrated circuit (RFIC) 161, a filter circuit 163, a switch circuit 164, and an antenna 165.

The filter circuit 163 is, for example, a band-pass filter. Note that the filter circuit 163 may be other types of filters. Additionally, the filter circuit 163 may be provided in plural.

The switch circuit 164 switches the connection of the antenna 165 to any one of the multiple filter circuits 163. Note that the antenna 165 may be provided in plural. In this case, the switch circuit 164 switches the electrical coupling between the multiple antennas 165 and the multiple filter circuits 163.

The input terminal 31 and the output terminal 32 of the LC circuit 101 are connected to the filter circuit 163 and the low-noise amplifier 151, respectively. The LC circuit 101 matches the impedance between the antenna 165 and the low-noise amplifier 151.

The low-noise amplifier 151 amplifies a reception signal Rxin received from the antenna 165 through the switch circuit 164, the filter circuit 163, and the LC circuit 101, and outputs an amplified signal Rxout to the RFIC 161.

The RFIC 161 demodulates the amplified signal Rxout supplied from the low-noise amplifier 151. Specifically, the RFIC 161 down-converts the amplified signal Rxout to generate a baseband signal, for example.

Although the configuration in which the LC circuit 101 is provided in the reception circuit 121 has been described, it is not limited thereto. The configuration may be such that, in the reception circuit 121, the LC circuit 102 or 103 is provided instead of the LC circuit 101. Here, when the LC circuit 103 is provided, the output terminal 32 and the input terminal 31 may be connected to the filter circuit 163 and the low-noise amplifier 151, respectively.

### Fifth Embodiment

The LC circuit 101 according to a fifth embodiment will be described. FIG. 10 is a circuit diagram of a transmission circuit 122 including the LC circuit 101. As illustrated in FIG. 10, the LC circuit 101 according to the fifth embodiment differs from the LC circuit 101 according to the first embodiment in that the LC circuit 101 is specifically incorporated into the transmission circuit.

The transmission circuit 122 includes a power amplifier 152 (amplifier), the RFIC 161, the filter circuit 163, the switch circuit 164, and the antenna 165.

The input terminal 31 and the output terminal 32 of the LC circuit 101 are connected to the power amplifier 152 and the filter circuit 163, respectively. The LC circuit 101 matches the impedance between the antenna 165 and the power amplifier 152.

The RFIC 161 supplies a transmission signal Txin to the power amplifier 152. The power amplifier 152 is, for example, a multi-stage power amplifier. Note that the power amplifier 152 may be a single-stage amplifier. The power amplifier 152 amplifies the transmission signal Txin supplied from the RFIC 161, and outputs an amplified signal Txout.

The amplified signal Txout is transmitted to the antenna 165 through the LC circuit 101, the filter circuit 163, and the switch circuit 164.

Although the configuration in which the LC circuit 101 is provided in the transmission circuit 122 has been described, it is not limited thereto. The configuration may be such that, in the transmission circuit 122, the LC circuit 102 or 103 is provided instead of the LC circuit 101. Here, when the LC circuit 103 is provided, the output terminal 32 and the input terminal 31 may be connected to the power amplifier 152 and the filter circuit 163, respectively.

### Sixth Embodiment

In the drawings, the x-axis, y-axis, and z-axis may be indicated. The x-axis, y-axis, and z-axis form a right-handed three-dimensional orthogonal coordinate system. Hereinafter, the direction of the arrow of the x-axis may be referred to as the x-axis + side, and the direction opposite to the arrow may be referred to as the x-axis – side. The same applies to the other axes. The z-axis + side and the x-axis – side may also be referred to as the "upper side" and "lower side", respectively. The z-axis direction may also be referred to as the "stacking direction". Additionally, a plane orthogonal to the x-axis, y-axis, or z-axis may be referred to as the yz-plane, zx-plane, or xy-plane, respectively. Here, a direction of rotation that is clockwise when viewed from the upper side toward the lower side is defined as the clockwise direction cw. Additionally, a direction of rotation that is counterclockwise when viewed from the upper side toward the lower side is defined as the counterclockwise direction ccw.

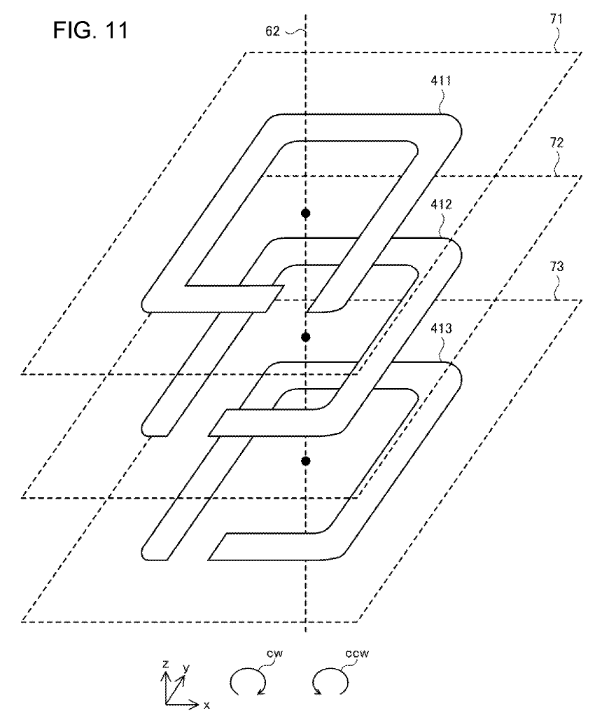

The LC circuit 101 according to a sixth embodiment will be described. FIG. 11 is a diagram illustrating an example of the layout of the inductors 311, 312, and 313 of the LC circuit 101. As illustrated in FIG. 11, the LC circuit 101 according to the fifth embodiment differs from the LC circuit 101 according to the first embodiment in that the specific arrangement of the inductors 311, 312 and 313 is indicated.

The inductors 311, 312, and 313 include windings 411 (second winding), 412 (first winding), and 413 (third winding), respectively.

The winding 412 is wound around an axis 62 (first axis) on a plane 72 (first plane) that intersects the axis 62. The winding 411 is wound around the axis 62 on a plane 71 (second plane) that faces the plane 72. The winding 413 is wound around the axis 62 on a plane 73 (third plane) that faces the plane 72.

In the present embodiment, the axis 62 is parallel to the z-axis. The plane 72 extends substantially parallel to the xy-plane. The plane 71 is provided on the upper side of the plane 72 and extends substantially parallel to the xy-plane. The plane 73 is provided on the lower side of the plane 72 and extends substantially parallel to the xy-plane.

The planes 71, 72, and 73 are, for example, surfaces of insulating layers stacked inside a multilayer substrate or a semiconductor chip.

The winding 412 is, for example, a metal electrode formed on the plane 72. The winding 412 has a first end and a second end respectively corresponding to the first end and the second end of the inductor 312. The winding 412 is wound, for example, around the axis 62 from the first end to the second end in the clockwise direction cw by an amount of three-quarters of a turn or more and less than one full turn.

The winding 411 is, for example, a metal electrode formed on the plane 71. The winding 411 has a first end and a second end respectively corresponding to the first end and the second end of the inductor 311. The winding 411 is wound, for example, around the axis 62 from the first end to the second end in the clockwise direction cw by an amount of three-quarters of a turn or more and less than one full turn.

The winding 413 is, for example, a metal electrode formed on the plane 73. The winding 413 has a first end and a second end respectively corresponding to the first end and the second end of the inductor 313. The winding 413 is wound, for example, around the axis 62 from the first end to the second end in the counterclockwise direction ccw by an amount of three-quarters of a turn or more and less than one full turn.

### Seventh Embodiment

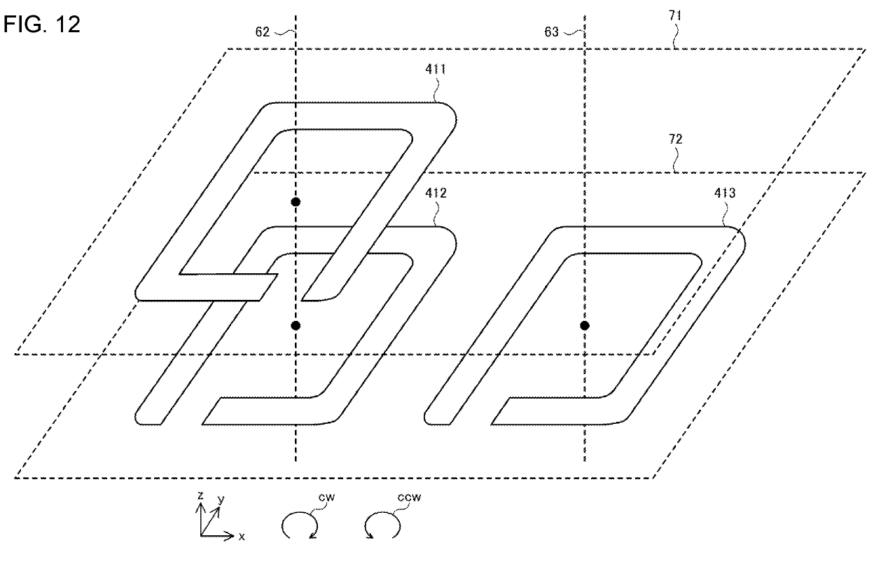

The LC circuit 101 according to a seventh embodiment will be described. FIG. 12 is a diagram illustrating another example of the layout of the inductors 311, 312, and 313 of the LC circuit 101. As illustrated in FIG. 12, the LC circuit 101 according to the seventh embodiment differs from the LC circuit 101 according to the sixth embodiment in that the windings 412 and 413 are provided on the same plane.

In the present embodiment, the winding 413 is wound around an axis 63 (third axis) that is substantially parallel to the axis 62 (first axis) on the plane 72 (first plane).

Specifically, the winding 413 is provided on the x-axis + side of the winding 412 on the plane 72. The axis 63 is parallel to the z-axis and is located on the x-axis + side of the axis 62.

The winding 413 is wound, for example, around the axis 63 from the first end to the second end in the clockwise direction cw by an amount of three-quarters of a turn or more and less than one full turn.

### Eighth Embodiment

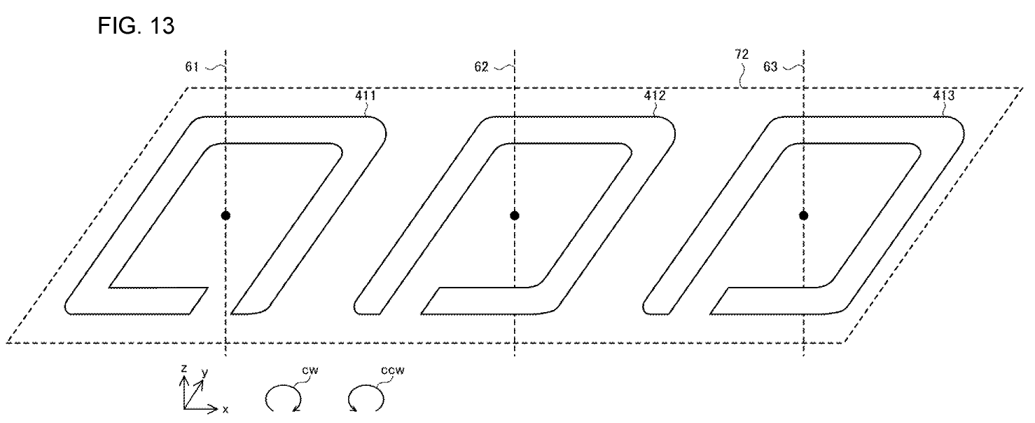

The LC circuit 101 according to an eighth embodiment will be described. FIG. 13 is a diagram illustrating yet another example of the layout of the inductors 311, 312, and 313 of the LC circuit 101. As illustrated in FIG. 13, the LC circuit 101 according to the eighth embodiment differs from the LC circuit 101 according to the seventh embodiment in that the windings 411 and 412 are provided on the same plane.

In the present embodiment, the winding 411 is wound around an axis 61 (second axis) substantially parallel to the axis 62 (first axis) on the plane 72 (first plane).

Specifically, the winding 411 is provided on the x-axis - side of the winding 412 on the plane 72. The axis 61 is parallel to the z-axis and is located on the x-axis - side of the axis 62.

The winding 411 is wound, for example, around the axis 61 from the first end to the second end in the counterclockwise direction ccw by an amount of three-quarters of a turn or more and less than one full turn.

### Ninth Embodiment

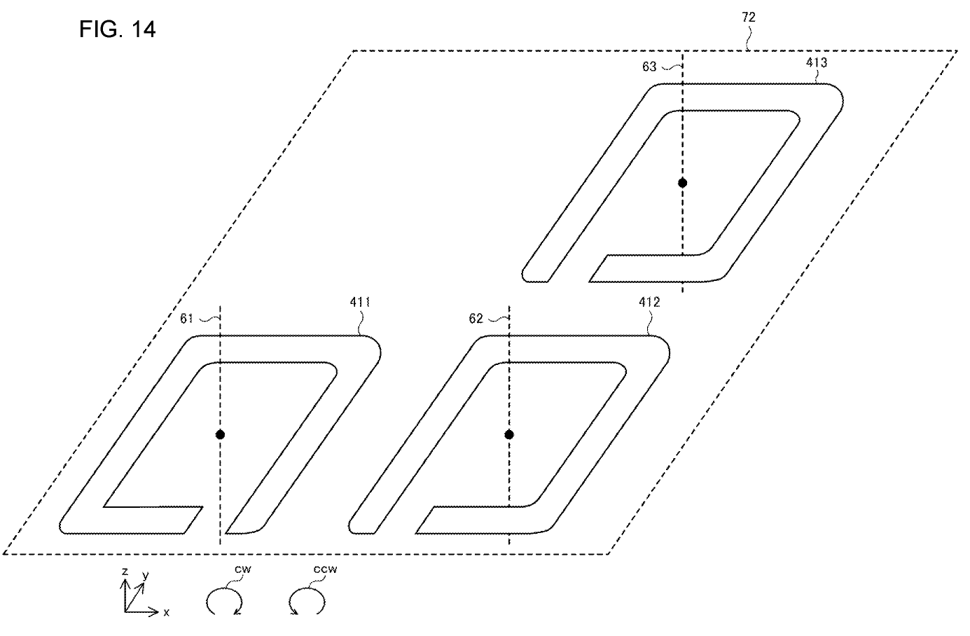

The LC circuit 101 according to a ninth embodiment will be described. FIG. 14 is a diagram illustrating a further example of the layout of the inductors 311, 312, and 313 of the LC circuit 101. As illustrated in FIG. 14, the LC circuit 101 according to the ninth embodiment differs from the LC circuit 101 according to the eighth embodiment in that the windings 411, 412, and 413 are arranged in an L-shape.

In the present embodiment, the axis 63 is located on the y-axis + side of the axis 62. The winding 413 is provided on the y-axis + side of the winding 412 on the plane 72.

The winding 413 is wound, for example, around the axis 63 from the first end to the second end in the clockwise direction cw by an amount of three-quarters of a turn or more and less than one full turn.

The exemplary embodiments of the present disclosure have been described so far. In the LC circuit 101, the inductor 311 has a first end electrically coupled to the input terminal 31 and a second end electrically coupled to ground. The capacitor 331 has a first end electrically coupled to the input terminal 31 and a second end. The inductor 312 has a first end electrically coupled to the second end of the capacitor 331 and a second end electrically coupled to ground, and is electromagnetically coupled to the inductor 311. The inductor 313 has a first end electrically coupled to the second end of the capacitor 331 and a second end electrically coupled to the output terminal 32, and is electromagnetically coupled to the inductor 312.

In this manner, with the configuration in which the inductor 312 and the inductor 311 are electromagnetically coupled, it is possible to allow the inductors 311 and 312 and the capacitor 331 to function as a π-type high-pass filter with a pole. Furthermore, with the configuration in which the inductor 312 and the inductor 313 are electromagnetically coupled to form an autotransformer, it is possible to allow the autotransformer to function as an impedance matching circuit. With the magnetic field effectively enhanced by sharing the inductor 312, it is possible to supplement the inductances of the inductors 311, 312, and 313. This makes it possible to reduce the size of the inductors 311, 312, and 313, thereby allowing the circuit size of the LC circuit 101 to be reduced. Accordingly, it is possible to provide an LC circuit that possesses the function of a high-pass filter with a pole and the function of impedance matching, and that allows the circuit size to be reduced.

Additionally, in the LC circuit 103, the capacitor 332 has a first end electrically coupled to the input terminal 31 and a second end electrically coupled to ground. The capacitor 333 has a first end electrically coupled to the second end of the capacitor 331 and a second end electrically coupled to ground.

With such a configuration, for the LC circuit 101 whose input impedance tends to be inductive due to the inclusion of multiple inductors, it is possible to enhance the capacitive nature of the input impedance. This makes it possible to, for example, make the input impedance closer to the real-valued reference impedance.

Moreover, in the LC circuit 101, the input terminal 31 is electrically coupled to the power amplifier 152. The output terminal 32 is electrically coupled to the antenna 165.

With such a configuration, it is possible to satisfactorily realize the function of impedance matching between the power amplifier 152 and the antenna 165 and the function of a high-pass filter with a pole using a small circuit size. This makes it possible to reduce the region occupied by the LC circuit 101 in the transmission circuit 122, thereby realizing the compact transmission circuit 122.

Furthermore, in the LC circuit 101, the input terminal 31 is electrically coupled to the antenna 165. The output terminal 32 is then electrically coupled to the low-noise amplifier 151.

With such a configuration, it is possible to satisfactorily realize the function of impedance matching between the low-noise amplifier 151 and the antenna 165 and the function of a high-pass filter with a pole using a small circuit size. This makes it possible to reduce the region occupied by the LC circuit 101 in the reception circuit 121, thereby realizing the compact reception circuit 121.

Additionally, in the LC circuit 101, the inductor 312 includes the winding 412 wound around the axis 62 on the plane 72 intersecting the axis 62. The inductor 311 includes the winding 411 wound around the axis 62 on the plane 71 facing the plane 72.

In this way, with the configuration in which the inductors 312 and 311 are arranged so that they are aligned in the stacking direction, it is possible to reduce the area of the region occupied by the inductors 312 and 311 when the plane 72 is viewed in plan. This makes it possible to increase the available space on the plane 71 or 72, thereby improving the flexibility of the layout. It is also possible to effectively enhance the electromagnetic coupling of the inductors 311 and 312.

Additionally, in the LC circuit 101, the inductor 312 includes the winding 412 wound around the axis 62 on the plane 72 intersecting the axis 62. The inductor 313 includes the winding 413 wound around the axis 62 on the plane 73 facing the plane 72.

In this way, with the configuration in which the inductors 312 and 313 are arranged so that they are aligned in the stacking direction, it is possible to reduce the area of the region occupied by the inductors 312 and 313 when the plane 72 is viewed in plan. This makes it possible to increase the available space on the plane 71 or 73, thereby improving the flexibility of the layout. It is also possible to effectively enhance the electromagnetic coupling of the inductors 311 and 313.

Additionally, in the LC circuit 101, the inductor 312 includes the winding 412 wound around the axis 62 on the plane 72 intersecting the axis 62. The inductor 311 includes the winding 411 wound around the axis 61, which is substantially parallel to the axis 62, on the plane 72.

In this way, with the configuration in which the inductors 312 and 311 are arranged so that they are aligned in the extending direction of the plane 72, it is possible to form the windings 412 and 411 even on a non-laminated substrate, thereby improving the design flexibility.

Additionally, in the LC circuit 101, the inductor 312 includes the winding 412 wound around the axis 62 on the plane 72 intersecting the axis 62. The inductor 313 includes the winding 413 wound around the axis 63, which is substantially parallel to the axis 62, on the plane 72.

In this way, with the configuration in which the inductors 312 and 313 are arranged so that they are aligned in the extending direction of the plane 72, it is possible to form the windings 412 and 413 even on a non-laminated substrate, thereby improving the design flexibility.

It should be noted that the embodiments described above are provided to facilitate understanding of the present disclosure and are not intended to limit the scope of the disclosure. The present disclosure may be modified or improved without departing from its spirit, and equivalents thereof are also included within the scope of the disclosure. That is, as long as the features of the present disclosure are retained, design modifications appropriately made by those skilled in the art to the respective embodiments are also encompassed within the scope of the disclosure. For example, the individual elements included in the embodiments, and their arrangements, materials, conditions, shapes, sizes, and so forth, are not limited to the examples described and may be appropriately altered. Moreover, it goes without saying that the embodiments are merely illustrative, and that partial substitution or combination of the configurations discussed in different embodiments is also possible, and such variations are likewise included within the scope of the present disclosure to the extent that they include the features of the disclosure.

What is claimed is:

1. An LC circuit comprising:
a first inductor having a first end electrically coupled to a first terminal, and a second end electrically coupled to ground;
a first capacitor having a first end electrically coupled to the first terminal, and a second end;
a second inductor having a first end electrically coupled to the second end of the first capacitor, and a second end electrically coupled to ground and electromagnetically coupled to the first inductor;
a third inductor having a first end electrically coupled to the second end of the first capacitor, and a second end electrically coupled to a second terminal and electromagnetically coupled to the second inductor.

2. The LC circuit according to claim 1, further comprising:
a second capacitor having a first end electrically coupled to the first terminal, and a second end electrically coupled to ground; and
a third capacitor having a first end electrically coupled to the second end of the first capacitor, and a second end electrically coupled to ground.

3. The LC circuit according to claim 1,
wherein the first terminal is electrically coupled to an amplifier, and
wherein the second terminal is electrically coupled to an antenna.

4. The LC circuit according to claim 2,
wherein the first terminal is electrically coupled to an amplifier, and
wherein the second terminal is electrically coupled to an antenna.

5. The LC circuit according to claim 1,
wherein the first terminal is electrically coupled to an antenna, and
wherein the second terminal is electrically coupled to an amplifier.

6. The LC circuit according to claim 2,
wherein the first terminal is electrically coupled to an antenna, and
wherein the second terminal is electrically coupled to an amplifier.

7. The LC circuit according to claim 1,
wherein the second inductor comprises a first winding wound around a first axis on a first plane intersecting the first axis, and
wherein the first inductor comprises a second winding wound around the first axis on a second plane facing the first plane.

8. The LC circuit according to claim 2,
wherein the second inductor comprises a first winding wound around a first axis on a first plane intersecting the first axis, and
wherein the first inductor comprises a second winding wound around the first axis on a second plane facing the first plane.

9. The LC circuit according to claim 1,
wherein the second inductor comprises a first winding wound around a first axis on a first plane intersecting the first axis, and
wherein the third inductor comprises a third winding wound around the first axis on a third plane facing the first plane.

10. The LC circuit according to claim 2,
wherein the second inductor comprises a first winding wound around a first axis on a first plane intersecting the first axis, and
wherein the third inductor comprises a third winding wound around the first axis on a third plane facing the first plane.

11. The LC circuit according to claim 1,
wherein the second inductor comprises a first winding wound around a first axis on a first plane intersecting the first axis, and
wherein the first inductor comprises a second winding wound around a second axis substantially parallel to the first axis on the first plane.

12. The LC circuit according to claim 2,
wherein the second inductor comprises a first winding wound around a first axis on a first plane intersecting the first axis, and
wherein the first inductor comprises a second winding wound around a second axis substantially parallel to the first axis on the first plane.

13. The LC circuit according to claim 1,
wherein the second inductor comprises a first winding wound around the first axis on a first plane intersecting the first axis, and
wherein the third inductor comprises a third winding wound around a third axis substantially parallel to the first axis on the first plane.

14. The LC circuit according to claim 2,
wherein the second inductor comprises a first winding wound around the first axis on a first plane intersecting the first axis, and
wherein the third inductor comprises a third winding wound around a third axis substantially parallel to the first axis on the first plane.
